(19) United States
(12) Patent Application Publication
(10) Pub. No.: US 2003/0219963 A1
(43) Pub. Date: Nov. 27, 2003

(54) Self-aligned method for fabricating epitaxial base bipolar transistor device

(75) Inventors: Kuei-Hung Shen, Hsinchu (TW); Shin-Chii Lu, Hsinchu (TW); Lurng-Shehng Lee, Hsinchu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/154,068

(22) Filed: May 23, 2002

(51) Int. Cl. H01L 21/22

(52) U.S. Cl. 438/550

(57) ABSTRACT

Within an epitaxial base bipolar transistor device and a method for fabricating the epitaxial base bipolar transistor device there is provided: (1) a monocrystalline semiconductor substrate which serves as a collector, in turn having formed thereupon; (2) an epitaxial base layer. Within the epitaxial base bipolar transistor device and method, there is further employed: (1) a pair of inward facing spacers formed over the epitaxial base layer and defining, at least in part, an aperture having at its bottom a portion of the epitaxial base layer; and (2) a pair of outward facing spacers formed over the epitaxial base layer and laminated to a pair of sides of the pair of inward facing spacers opposite the aperture; such that (3) an emitter layer may be formed into the aperture and contacting the epitaxial base layer. The foregoing two pair of spacer layers provide for efficient fabrication of the epitaxial base bipolar transistor device, with enhanced process latitude.

### BACKGROUND OF THE INVENTION

1. Field of the Invention

The present invention relates generally to epitaxial base bipolar transistor devices. More particularly, the present invention relates to self-aligned methods for fabricating epitaxial base bipolar transistor devices.

2. Description of the Related Art

Common in the art of semiconductor integrated circuit microelectronic fabrication, in addition to the fabrication of field effect transistor (FET) devices within semiconductor integrated circuit microelectronic fabrications, is the fabrication of bipolar transistor devices within semiconductor integrated circuit microelectronic fabrications.

Bipolar transistor devices are desirable in the art of semiconductor integrated circuit microelectronic fabrication insofar as bipolar transistor devices may often be designed and fabricated such as to provide semiconductor integrated circuit microelectronic fabrications which operate at enhanced speeds, in comparison with otherwise equivalent semiconductor integrated circuit microelectronic fabrications alternatively having fabricated therein field effect transistor (FET) devices.

While bipolar transistor devices are thus clearly desirable in the art of semiconductor integrated circuit microelectronic fabrication and often essential in the art of semiconductor integrated circuit microelectronic fabrication, bipolar transistor devices are nonetheless not entirely without problems in the art of semiconductor integrated circuit microelectronic fabrication. In that regard, and insofar as bipolar transistor devices are generally more complex transistor devices than field effect transistor (FET) devices, bipolar transistor devices are often difficult to efficiently fabricate within semiconductor integrated circuit microelectronic fabrications with enhanced process latitude.

It is thus desirable in the art of semiconductor integrated circuit microelectronic fabrication to provide methods and materials which may be employed for efficiently fabricating bipolar transistor devices within semiconductor integrated circuit microelectronic fabrications, with enhanced process latitude.

It is towards the foregoing object that the present invention is directed.

Various bipolar transistor devices having desirable properties, and methods for fabrication thereof, have been disclosed within the art of semiconductor integrated circuit microelectronic fabrication.

Included among the bipolar transistor devices and methods for fabrication thereof, but not limiting among the bipolar transistor devices and methods for fabrication thereof, are bipolar transistor devices and methods for fabrication thereof disclosed within: (1) Welbourne et al., in U.S. Pat. No. 4,927,774 (a method for fabricating, with enhanced performance and enhanced efficiency, a bipolar transistor device within a semiconductor integrated circuit microelectronic fabrication, by fabricating, in a self-aligned fashion, the bipolar transistor device within the semiconductor integrated circuit microelectronic fabrication absent sidewall contact of an emitter within the bipolar transistor device with a base within the bipolar transistor device); (2) Burghartz et al., in “APCVD-Grown Self-Aligned SiGe-Base HBTs,” IEEE 1993 Bipolar Circuits and Technology Meeting, pp. 55-62 (a bipolar transistor device fabricated with enhanced performance, by fabricating the bipolar transistor device with a silicon-germanium alloy base layer rather than a silicon base layer); (3) Harame et al., in “Si/SiGe Epitaxial-Base Transistors—Part II: Process Integration and Analog Applications,” IEEE Trans. On Electron Devices, Vol. 42(3), March 1995, pp. 469-82 (a compendium of methods for fabricating bipolar transistor devices with enhanced performance, by fabricating the bipolar transistor devices with silicon-germanium alloy base layers); and (4) Koscielniak et al, in U.S. Pat. No. 6,020,246 (a method for efficiently fabricating a bipolar transistor device with enhanced alignment, by fabricating the bipolar transistor device in a self-aligned fashion, and with a sacrificial emitter core layer).

The disclosure of each of the foregoing references is incorporated herein fully by reference.

Desirable in the art of semiconductor integrated circuit microelectronic fabrication are additional methods and materials which may be employed for efficiently fabricating bipolar transistor devices within semiconductor integrated circuit microelectronic fabrications, with enhanced process latitude.

It is towards the foregoing object that the present invention is directed.

### SUMMARY OF THE INVENTION

A first object of the present invention is to provide a bipolar transistor device and a method for fabricating the bipolar transistor device.

A second object of the present invention is to provide the bipolar transistor device and the method for fabricating the bipolar transistor device in accord with the first object of the present invention, wherein the bipolar transistor device may be efficiently fabricated with enhanced process latitude.

In accord with the objects of the present invention, there is provided by the present invention an epitaxial base bipolar transistor device and a method for fabricating the epitaxial base bipolar transistor device.

In accord with the present invention, the epitaxial base bipolar transistor device comprises, in a first instance, a monocrystalline semiconductor substrate which serves as a collector. The epitaxial base bipolar transistor device also comprises an epitaxial base layer formed upon the monocrystalline semiconductor substrate. The epitaxial base bipolar transistor device also comprises a pair of inward facing spacers formed over the epitaxial base layer and defining, at least in part, an aperture having at its bottom a portion of the epitaxial base layer. The epitaxial base bipolar transistor device also comprises a pair of outward facing spacers formed over the epitaxial base layer and laminated to a pair of sides of the pair of inward facing spacers opposite the aperture. Finally, the epitaxial base bipolar transistor device also comprises an emitter layer formed into the aperture and contacting the epitaxial base layer.

The epitaxial base bipolar transistor device in accord with the present invention contemplates a method for fabricating the epitaxial base bipolar transistor device in accord with the present invention.

The present invention provides a bipolar transistor device and a method for fabricating the bipolar transistor device, wherein the bipolar transistor device may be efficiently fabricated with enhanced process latitude.

The present invention realizes the foregoing objects by fabricating the bipolar transistor device as an epitaxial base bipolar transistor device comprising, in a first instance: (1) a monocrystalline semiconductor substrate which serves as a collector, in turn having formed thereupon; (2) an epitaxial base layer. Within the epitaxial base bipolar transistor in accord with the present invention there is further defined an aperture having at its bottom a portion of the epitaxial base layer, where the aperture has formed therein an emitter layer contacting the epitaxial base layer, and further wherein the aperture is defined by: (1) a pair of inward facing spacers, the pair of inward facing spacers in turn having laminated thereto; (2) a pair of outward facing spacers at a pair of sides of the inward facing spacers opposite the aperture. Within the context of the present invention, by employing the foregoing two pair of spacers for defining a contact portion of the emitter layer with respect to an epitaxial base layer, an epitaxial base bipolar transistor device may be efficiently fabricated with enhanced process latitude.

As is understood by a person skilled in the art, and in accord with further description below, the present invention provides in-part a self-aligned method for fabricating an epitaxial base bipolar transistor, where is turn the self-aligned method provides for: (1) reduced fabrication difficulties related to misalignment and inadequate photolithographic focusing; (2) an ability to effect feature sizes smaller than a minimum photolithographically resolvable feature size; and (3) enhanced epitaxial bipolar transistor performance, such as but not limited to reduced parasitic capacitances and parasitic resistances.

### BRIEF DESCRIPTION OF THE DRAWINGS

The objects, features and advantages of the present invention are understood within the context of the Description of the Preferred Embodiment, as set forth below. The Description of the Preferred Embodiment is understood within the context of the accompanying drawings, which form a material part of this disclosure, wherein:

FIG. 1, FIG. 2, FIG. 3, FIG. 4, FIG. 5, FIG. 6 and FIG. 7 show a series of schematic cross-sectional diagrams illustrating the results of progressive stages of fabricating, in accord with a preferred embodiment of the present invention, an epitaxial base bipolar transistor device within a semiconductor integrated circuit microelectronic fabrication.

### DESCRIPTION OF THE PREFERRED EMBODIMENT

The present invention provides a bipolar transistor device and a method for fabricating the bipolar transistor device, wherein the bipolar transistor device may be efficiently fabricated with enhanced process latitude.

The present invention realizes the foregoing objects by fabricating the bipolar transistor device as an epitaxial base bipolar transistor device comprising, in a first instance: (1) a monocrystalline semiconductor substrate which serves as a collector, in turn having formed thereupon; (2) an epitaxial base layer. Within the epitaxial base bipolar transistor in accord with the present invention there is further defined an aperture having at its bottom a portion of the epitaxial base layer, where the aperture has formed therein an emitter layer contacting the epitaxial base layer, and further wherein the aperture is defined by: (1) a pair of inward facing spacers, the pair of inward facing spacers in turn having laminated thereto; (2) a pair of outward facing spacers at a pair of sides of the inward facing spacers opposite the aperture. Within the context of the present invention, by employing the foregoing two pair of spacers for defining a contact portion of the emitter layer with respect to an epitaxial base layer, an epitaxial base bipolar transistor device may be efficiently fabricated with enhanced process latitude.

Although not necessarily specifically illustrated within the preferred embodiment of the present invention, an epitaxial base bipolar transistor device fabricated in accord with the present invention may be fabricated (more preferably) as an N-P-N (emitter-base-collector) epitaxial base bipolar transistor device or (less preferably) as a P-N-P (emitter-base-collector) epitaxial base bipolar transistor device, provided appropriate dopant levels in accord with an epitaxial base bipolar transistor device in accord with the present invention.

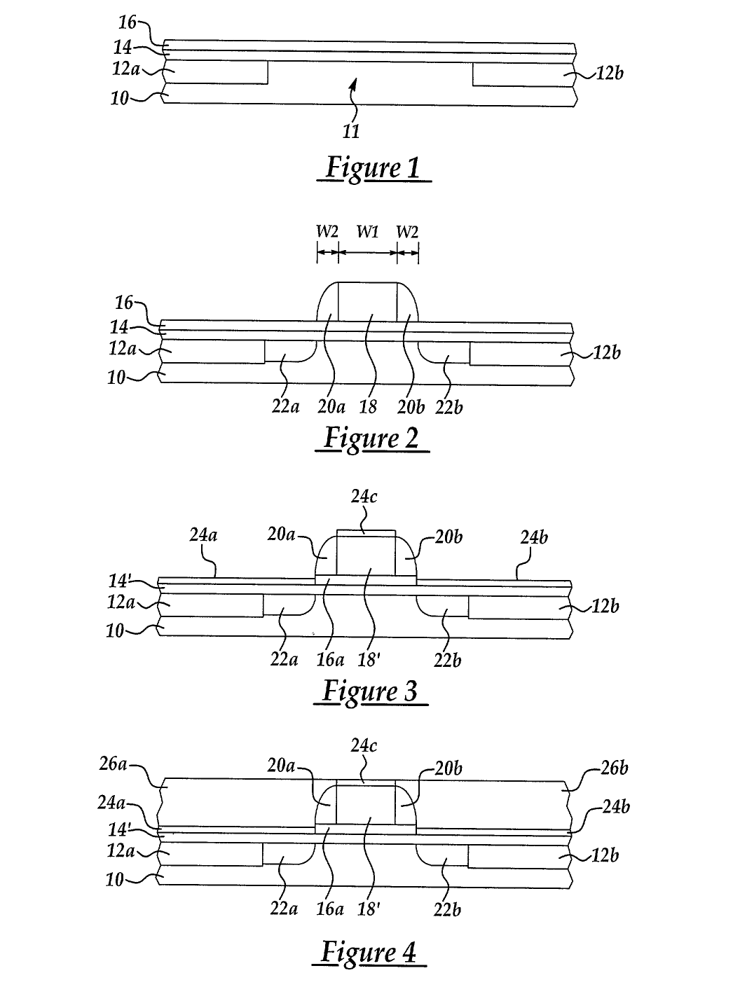

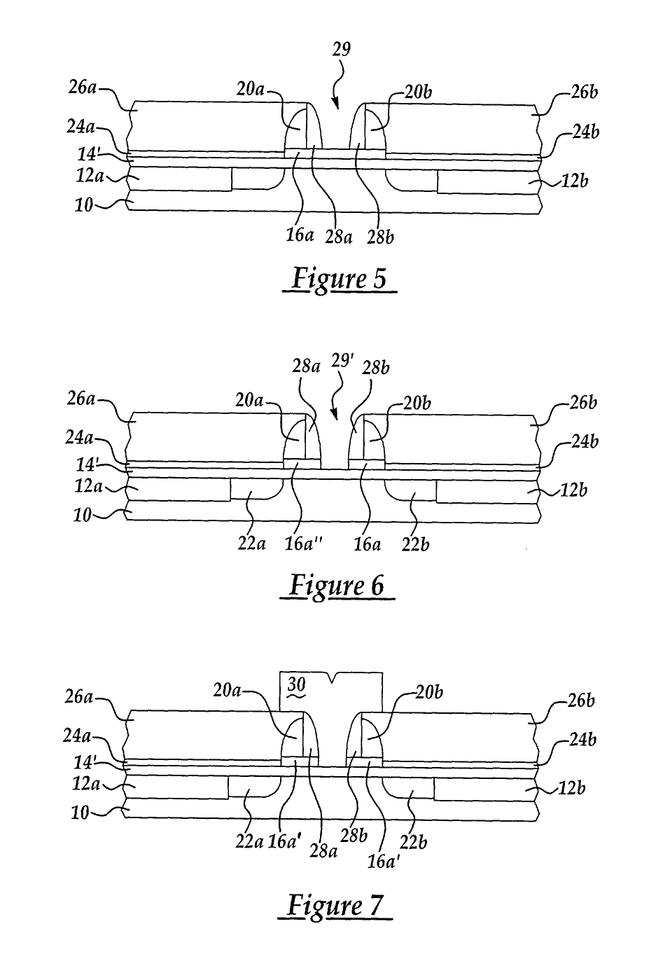

Referring now to FIG. 1 to FIG. 7, there is shown a series of schematic cross-sectional diagrams illustrating the results of progressive stages of fabricating, in accord with a preferred embodiment of the present invention, an epitaxial base bipolar transistor device within a semiconductor integrated circuit microelectronic fabrication.

Shown in FIG. 1 is a schematic cross-sectional diagram of the semiconductor integrated circuit microelectronic fabrication at an early stage in fabrication therein of the epitaxial base bipolar transistor device in accord with the preferred embodiment of the present invention.

Shown in FIG. 1, in a first instance, is a semiconductor substrate 10, having formed therein a pair of isolation region 12a and 12b which define an active region 11 of the semiconductor substrate 10.

Within the preferred embodiment of the present invention with respect to the semiconductor substrate 10, and although semiconductor substrates are known in the art of semiconductor integrated circuit microelectronic fabrication with various semiconductor compositions (i.e., silicon, germahium, silicon-germanium alloy and compound (i.e., II-VI and III-V)) semiconductor compositions, either dopant polarity, several dopant concentrations and various crystallographic orientations (of which any of the foregoing might under certain circumstances be employed within the present invention), for the preferred embodiment of the present invention, the semiconductor substrate 10 is typically and preferably a (100) silicon semiconductor substrate having an N- or (more preferably) a P-dopant concentration. Similarly, and although not specifically illustrated within the schematic cross-sectional diagram of FIG. 1, the semiconductor substrate 10 serves in part as a collector within the epitaxial base bipolar transistor device in accord with the present invention. In that regard, the semiconductor substrate may also have formed therein a more heavily doped sub-collector region as is illustrated in greater detail within the references (i.e., see in particular Koscielniak et al., U.S. Pat. No. 6,020,246) cited within the Description of the Related Art.

Within the preferred embodiment of the present invention with respect to the pair of isolation regions 12a and 12b, and although it is known in the art of semiconductor integrated circuit microelectronic fabrication that isolation regions may be formed within semiconductor substrates while employing methods including but not limited to isolation region thermal growth methods and isolation region deposition/patterning methods (to form isolation regions such as but not limited to shallow trench isolation (STI) regions, deep trench isolation regions and local oxidation of silicon (LOCOS) isolation regions), for the preferred embodiment of the present invention, the pair of isolation regions 12a, and 12b is typically and preferably formed as a pair of local oxidation of silicon (LOCOS) isolation regions, although the pair of isolation regions may be formed as other types of isolation regions.

Shown also within the schematic cross-sectional diagram of FIG. 1, and formed upon the semiconductor substrate 10 having formed therein the pair of isolation regions 12a and 12b which define the active region 11 of the semiconductor substrate 10, is a blanket intrinsic epitaxial base layer 14, in turn having formed thereupon a blanket dielectric layer 16.

Within the preferred embodiment of the present invention with respect to the blanket intrinsic epitaxial base layer 14 (which is formed epitaxially as a monocrystalline material upon the active region 11 of the semiconductor substrate 10 and as a polycrystalline material upon the pair of isolation regions 12a and 12b), the blanket intrinsic epitaxial base layer 14 may be formed of intrinsic epitaxial base materials as are conventional in the art of semiconductor integrated circuit microelectronic fabrication, including but not limited to intrinsic epitaxial silicon base materials, intrinsic epitaxial germanium base materials and intrinsic epitaxial silicon-germanium alloy (up to about 30 atomic percent germanium, and more typically and preferably from about 0 to about 25 atomic percent germanium) base materials, as well as laminate materials thereof. Typically and preferably, the blanket intrinsic epitaxial base layer 14 is formed to a thickness of from about 300 to about 700 angstroms of a silicon or silicon-germanium alloy intrinsic epitaxial base material, or laminate thereof, formed upon the semiconductor substrate 10 having formed therein the pair of isolation regions 12a and 12b.

Within the preferred embodiment of the present invention with respect to the blanket dielectric layer 16, the blanket dielectric layer 16 may be formed of dielectric materials as are conventional in the art of semiconductor integrated circuit microelectronic fabrication, such as, in particular, silicon oxide dielectric materials, silicon nitride dielectric materials and silicon oxynitride dielectric materials. For the preferred embodiment of the present invention, the blanket dielectric layer 16 is typically and preferably formed of a silicon oxide dielectric material, formed to a thickness of from about 300 to about 500 angstroms upon the blanket intrinsic epitaxial base layer 14. As is understood within the context of additional disclosure below, the blanket dielectric layer 16 is also formed of a dielectric material having appropriate etch selectivity properties with respect to additional layers formed thereupon.

Referring now to FIG. 2, there is shown a schematic cross-sectional diagram illustrating the results of further processing of the semiconductor integrated circuit microelectronic fabrication whose schematic cross-sectional diagram is illustrated in FIG. 1.

Shown in FIG. 2 is a schematic cross-sectional diagram of a semiconductor integrated circuit microelectronic fabrication otherwise equivalent to the semiconductor integrated circuit microelectronic fabrication whose schematic cross-sectional diagram is illustrated in FIG. 1, but wherein there is formed upon the blanket dielectric layer 16, and nominally centered within the active region 11 of the semiconductor substrate 10, a patterned sacrificial layer 18 having formed adjoining a pair of its sidewalls a pair of first spacer layers 20a and 20b. As is illustrated within the schematic cross-sectional diagram of FIG. 2, the pair of first spacer layers 20a and 20b is formed as a pair of outward facing spacer layers.

Within the preferred embodiment of the present invention with respect to the patterned sacrificial layer 18, the patterned sacrificial layer 18 may be formed from any of several sacrificial materials as are conventional in the art of semiconductor integrated circuit microelectronic fabrication, including but not limited to sacrificial conductor materials, sacrificial semiconductor materials and sacrificial dielectric materials, provided that the patterned sacrificial layer 18 is formed of a sacrificial material with an etch specificity with respect to the pair of first spacer layers 20a and 20b. More typically and preferably, the patterned sacrificial layer 18 is formed of a polysilicon sacrificial material, formed to a thickness of from about 4000 to about 6000 angstroms upon the blanket dielectric layer 16, and nominally centered over the active region 11 of the semiconductor substrate 10.

Within the preferred embodiment of the present invention with respect to the pair of first spacer layers 20a and 20b, the pair of first spacer layers 20a and 20b is typically and preferably formed of a dielectric material which, as indicated above, has an etch specificity with respect to at least the patterned sacrificial layer 18, and preferably also the blanket dielectric layer 16. Typically and preferably, the pair of first spacer layers 20a and 20b is formed of a silicon nitride material or a silicon oxynitride material when the blanket dielectric layer 16 is formed of a silicon oxide dielectric material, although other materials may also be employed for forming the pair of first spacer layers 20a and 20b. Typically and preferably, the pair of first spacer layers 20a and 20b is formed with a linewidth W2 of from about 500 angstroms to about 1500 angstroms projected upon the blanket dielectric layer 16.

Finally, there is also shown within the schematic cross-sectional diagram of FIG. 2 a pair of extrinsic base regions 22a and 22b formed into the active region of the semiconductor substrate 10 while employing the patterned sacrificial layer 18 and the pair of first spacer layers 20a and 20b as an ion implant mask layer (i.e., the pair of extrinsic base regions 22a and 22b is formed separated by and aligned to the pair of first spacer layers 20a and 20b).

Within the preferred embodiment of the present invention, the pair of extrinsic base regions 22a and 22b is formed via an ion implant method as is otherwise generally conventional in the art of semiconductor integrated circuit microelectronic fabrication.

Referring now to FIG. 3, there is shown a schematic cross-sectional diagram illustrating the results of further processing of the semiconductor integrated circuit microelectronic fabrication whose schematic cross-sectional diagram is illustrated in FIG. 2.

Shown in FIG. 3 is a schematic cross-sectional diagram of a semiconductor integrated circuit microelectronic fabrication otherwise equivalent to the semiconductor integrated circuit microelectronic fabrication whose schematic cross-sectional diagram is illustrated in FIG. 2, but wherein, in a first instance, the blanket dielectric layer 16 has been patterned to form a patterned dielectric layer 16a, while employing the patterned sacrificial layer 18 and the pair of first spacer layers 20a and 20b as an etch mask layer.

Within the preferred embodiment of the present invention, the blanket dielectric layer 16 may be patterned to form the patterned dielectric layer 16a while employing the patterned sacrificial layer 18 and the pair of first spacer layers 20a and 20b as an etch mask layer, while further employing etch methods, and in particular selective anisotropic etch methods or selective isotropic etch methods, as are otherwise generally conventional in the art of semiconductor integrated circuit microelectronic fabrication.

Similarly, there is also shown within the schematic cross-sectional diagram of FIG. 3, after having patterned the blanket dielectric layer 16 to form the patterned dielectric layer 16a: (1) a pair of patterned metal silicide layers 24a and 24b formed upon corresponding portions of a partially consumed blanket intrinsic epitaxial base layer 14′ formed from the blanket intrinsic epitaxial intrinsic base layer 14; and (2) a patterned metal silicide layer 24c formed upon a partially consumed sacrificial layer 18′ (when formed of a polysilicon material) formed from the patterned sacrificial layer 18.

Within the preferred embodiment of the present invention, the series of patterned metal silicide layers 24a, 24b and 24c is typically and preferably formed employing a blanket metal layer deposition and thermal annealing self-aligned silicide formation method as is otherwise generally conventional in the art of semiconductor integrated microelectronic fabrication, to form the series of patterned metal silicide layers 24a, 24b and 24c. As is similarly also understood by a person skilled in the art, the series of patterned metal silicide layers 24a, 24b and 24c is optional within the present invention any may not be employed or formed under circumstances where process integration difficulties are encountered, although the pair of patterned metal silicide layers 24a and 24b often provides enhanced performance within an epitaxial base bipolar transistor device fabricated in accord with the present invention. When the series of patterned metal silicide layers 24a, 24b and 24c is not formed, there will remain in accord with the preferred embodiment of the present invention the blanket intrinsic epitaxial base layer 14 rather than the partially consumed blanket intrinsic epitaxial base layer 14′. As is yet similarly also understood by a person skilled in the art, the patterned metal silicide layer 24c and the partially consumed patterned sacrificial layer 18′, in an aggregate, serve the purpose of the patterned sacrificial layer 18 within the preferred embodiment of the present invention.

Referring now to FIG. 4, there shown a schematic cross-sectional diagram illustrating the results of further processing of the semiconductor integrated circuit microelectronic fabrication whose schematic cross-sectional diagram is illustrated in FIG. 3.

Shown in FIG. 4 is a schematic cross-sectional diagram of a semiconductor integrated circuit microelectronic fabrication otherwise equivalent to the semiconductor integrated circuit microelectronic fabrication whose schematic cross-sectional diagram is illustrated in FIG. 3, but wherein there has been formed adjoining the pair of first spacer layers 20a and 20b and the patterned metal silicide layer 24c a pair of patterned planarized pre-metal dielectric (PMD) layers 26a and 26b.

Within the preferred embodiment of the present invention, the pair of patterned planarized pre-metal dielectric layers 26a and 26b may be formed employing planarizing methods, such as but not limited to chemical mechanical polish (CMP) planarizing methods and reactive ion etch (RIE) etchback planarizing methods (but in particular chemical mechanical polish (CMP) planarizing methods), as are otherwise generally conventional in the art of semiconductor integrated circuit microelectronic fabrication. Typically and preferably, the pair of patterned planarized pre-metal dielectric (PMD) layers 26a and 26b is formed of a silicon oxide dielectric material or silicon oxide/silicon nitride laminated dielectric material, generally formed employing a chemical vapor deposition (CVD) method. As is also understood by a person skilled in the art, the patterned metal silicide layer 24c and the partially consumed patterned sacrificial layer 18′ (or in the alternative the patterned sacrificial layer 18 alone) serve as a planarizing stop layer when forming the pair of patterned planarized pre-metal dielectric (PMD) layers 26a and 26b from a corresponding blanket pre-metal dielectric layer formed upon the semiconductor integrated circuit microelectronic fabrication whose schematic cross-sectional diagram is illustrated in FIG. 3.

Referring now to FIG. 5, there is shown a schematic cross-sectional diagram illustrating the results of further processing of the semiconductor integrated circuit microelectronic fabrication whose schematic cross-sectional diagram is illustrated in FIG. 4.

Shown in FIG. 5 is a schematic cross-sectional diagram of a semiconductor integrated circuit microelectronic fabrication otherwise equivalent to the semiconductor integrated circuit microelectronic fabrication whose schematic cross-sectional diagram is illustrated in FIG. 4, but wherein, in a first instance, the patterned metal silicide layer 24c and the partially consumed patterned sacrificial layer 18′ (or alternatively the patterned sacrificial layer 18 alone), have been stripped to leave exposed a first aperture defined by the pair of patterned pre-metal dielectric (PMD) layers 26a and 26b and the pair of first spacer layers 20a and 20b.

Within the preferred embodiment of the present invention, the patterned metal silicide layer 24c and the partially consumed patterned sacrificial layer 18′ (or alternatively the patterned sacrificial layer 18 alone) may be stripped from the semiconductor integrated circuit microelectronic fabrication whose schematic cross-sectional diagram is illustrated in FIG. 4 to provide in part the semiconductor integrated circuit microelectronic fabrication whose schematic cross-sectional diagram is illustrated in FIG. 5, while employing stripping methods as are otherwise conventional in the art of semiconductor integrated circuit microelectronic fabrication.

Shown also within the schematic cross-sectional diagram of FIG. 5 and formed within the first aperture defined by the pair of patterned pre-metal dielectric (PMD) layers 26a and 26b and the pair of first spacer layers 20a and 20b, is a pair of second spacer layers 28a and 28b. As is illustrated within the schematic cross-sectional diagram of FIG. 5, and in comparison with the pair of first spacer layers 20a and 20b, the pair of second spacer layers 28a and 28b is formed inward facing to define a second aperture 29. Similarly, and as is also illustrated within the schematic cross-sectional diagram of FIG. 5, the pair of second spacer layers 28a and 28b is laminated to the pair of first spacer layers 20a and 20b, which in turn are further separated from the second aperture 29, which since the pair of second spacers 28a and 28b is formed in a self-aligned fashion may be of a linewidth less than a minimum photolithographically resolvable linewidth.

Within the preferred embodiment of the present invention, the pair of second spacer layers 28a and 28b may be formed employing methods and materials as are otherwise analogous or equivalent to the methods and materials employed for forming the pair of first spacer layers 20a and 20b. However, while the pair of first spacer layers 20a and 20b is formed of a dielectric material, the pair of second spacer layers 28a and 28b may be formed of materials selected from the group including but not limited to dielectric materials and semiconductor materials, depending upon design considerations when fabricating an epitaxial base bipolar transistor device in accord with the present invention. Such design considerations may include, but are not limited to, an available thickness of a patterned sacrificial layer, such the patterned sacrificial layer 18, which in turn will typically dictate an available linewidth of a pair of first spacer layers, such as the pair of first spacer layers 20a and 20b. As is further understood by a person skilled in the art, the available linewidth of the pair of first spacer layers in turn in part defines a location of a pair of extrinsic base regions, such as the pair of extrinsic regions 22a and 22b, within an epitaxial base bipolar transistor device in accord with the present invention. Thus, as is yet further understood by a person skilled in the art, the presence of two pair of spacer layers when fabricating an epitaxial base bipolar transistor device in accord with the present invention and the preferred embodiment of the present invention provides for efficient fabrication of the epitaxial base bipolar transistor device within a semiconductor integrated circuit microelectronic fabrication, with enhanced process latitude.

Referring now to FIG. 6, there is shown a schematic cross-sectional diagram illustrating the results of further processing of the semiconductor integrated circuit microelectronic fabrication whose schematic cross-sectional diagram is illustrated in FIG. 5.

Shown in FIG. 6 is a schematic cross-sectional diagram of a semiconductor integrated circuit microelectronic fabrication otherwise equivalent to the semiconductor integrated circuit microelectronic fabrication whose schematic cross-sectional diagram is illustrated in FIG. 5, but wherein the patterned dielectric layer 16a has been further patterned to form a pair of further patterned dielectric layers 16a′ and 16a″, while employing in part the pair of second spacer layers 28a and 28b as an etch mask layer, to thus form from the second aperture 29 as illustrated within the schematic cross-sectional diagram of FIG. 5 an elongated second aperture 29′ which exposes a portion of the partially consumed blanket intrinsic epitaxial base layer 14′ (or alternatively blanket epitaxial base layer 14). Incident to forming the pair of further patterned dielectric layers 16a′ and 16a″, given appropriate mateirals considerations, there may also be some etching of the pair of patterned planarized pre-metal dielectric (PMD) layers 26a and 26b, although such is not specifically illustrated within the schematic cross-sectional diagram of FIG. 6. Within the preferred embodiment of the present invention, the elongated second aperture 29′, which for reasons as noted above also may be less than a minimally photolithographically resolvable linewidth W1 employed when fabricating the patterned sacrificial layer 18 as illustrated within the schematic cross-sectional diagram of FIG. 2.

Within the preferred embodiment of the present invention, the patterned dielectric layer 16a may be further patterned to form the pair of further patterned dielectric layers 16a′ and 16a″ while employing methods and materials as are otherwise conventional in the art of semiconductor integrated circuit microelectronic fabrication, which will typically and preferably, but not exclusively, include anisotropic and isotropic etch methods. Within the context of the preferred embodiment of the present invention, wet chemical etch methods are often preferred for etching the patterned dielectric layer 16a when forming the pair of twice patterned dielectric layers 16a′ and 16a″, since such etch methods provide for less damage to a blanket intrinsic epitaxial base layer, such as the partially consumed blanket intrinsic epitaxial base layer 14′.

Referring now to FIG. 7, there is shown a schematic cross-sectional diagram illustrating the results of further processing of the semiconductor integrated circuit microelectronic fabrication whose schematic cross-sectional diagram is illustrated in FIG. 6.

Shown in FIG. 7 is a schematic cross-sectional diagram of a semiconductor integrated circuit microelectronic fabrication otherwise equivalent to the semiconductor integrated circuit microelectronic fabrication whose schematic cross-sectional diagram is illustrated in FIG. 6, but wherein there has been formed within the elongated second aperture 29′, and contacting the partially consumed blanket intrinsic epitaxial base layer 14′, an emitter layer 30.

Within the preferred embodiment of the present invention, the emitter layer 30 may be formed employing emitter layer deposition and patterning methods as are otherwise conventional in the art of semiconductor integrated circuit microelectronic fabrication. Typically and preferably, the emitter layer 30 is formed of a polysilicon emitter material of appropriate dopant polarity and concentration, although such is not necessarily required within the present invention and the preferred embodiment of the present invention.

Upon fabricating the semiconductor integrated circuit microelectronic fabrication whose schematic cross-sectional diagram is illustrated in FIG. 7, there is efficiently fabricated within the semiconductor integrated circuit microelectronic fabrication an epitaxial base bipolar transistor, with enhanced process latitude.

The present invention realizes the foregoing objects by fabricating the epitaxial base bipolar transistor device as comprising, in a first instance: (1) a monocrystalline semiconductor substrate which serves as a collector, in turn having formed thereupon; (2) an epitaxial base layer. Within the epitaxial base bipolar transistor in accord with the present invention there is further defined an aperture having at its bottom a portion of the epitaxial base layer, where the aperture has formed therein an emitter layer contacting the epitaxial base layer, and further wherein the aperture is defined by: (1) a pair of inward facing spacers, the pair of inward facing spacers in turn having laminated thereto; (2) a pair of outward facing spacers at a pair of sides of the inward facing spacers opposite the aperture. Within the context of the present invention, by employing the foregoing two pair of spacers for defining a contact portion of the emitter layer with respect to an epitaxial base layer, an epitaxial base bipolar transistor device may be efficiently fabricated with enhanced process latitude.

As is understood by a person skilled in the art, the preferred embodiment of the present invention is illustrative of the present invention rather than limiting of the present invention. Revisions and modifications may be made to methods, materials, structures and dimensions employed for fabricating an epitaxial base bipolar transistor in accord with the preferred embodiment of the present invention, while still fabricating an epitaxial base bipolar transistor in accord with the present invention, further in accord with the appended claims.

What is claimed is:

1. An epitaxial base bipolar transistor device comprising:
a monocrystalline semiconductor substrate which serves as a collector;
an epitaxial base layer formed upon the monocrystalline semiconductor substrate;
a pair of inward facing spacers formed over the epitaxial base layer and defining, at least in part, an aperture having at its bottom a portion of the epitaxial base layer;
a pair of outward facing spacers formed over the epitaxial base layer and laminated to a pair of sides of the pair of inward facing spacers opposite the aperture; and
an emitter layer formed into the aperture and contacting the epitaxial base layer.

2. The epitaxial base bipolar transistor of claim 1 wherein the epitaxial base bipolar transistor is an N-P-N epitaxial base bipolar transistor.

3. The epitaxial base bipolar transistor of claim 1 wherein the epitaxial base bipolar transistor in a P-N-P epitaxial base bipolar transistor.

4. The epitaxial base bipolar transistor of claim 1 wherein the epitaxial base layer is formed from an epitaxial base material selected from the group consisting of silicon epitaxial materials, germanium epitaxial materials and silicon-germanium alloy epitaxial materials.

5. The epitaxial base bipolar transistor of claim 1 wherein;
the pair of inward facing spacers is formed from a material selected from the group consisting of dielectric materials and semiconductor materials; and
the pair of outward facing spacers is formed from a dielectric material.

6. The epitaxial base bipolar transistor of claim 1 further comprising a pair of extrinsic base regions formed within the semiconductor substrate, the pair of extrinsic base regions being separated by and aligned with the pair of outward facing spacers.

7. A method for fabricating an epitaxial base bipolar transistor device comprising:
providing a monocrystalline semiconductor substrate which serves as a collector;
forming upon the monocrystalline semiconductor substrate an epitaxial base layer;
forming over the epitaxial base layer a pair of inward facing spacers, the pair of inward facing spacers defining, at least in part, an aperture having at its bottom a portion of the epitaxial base layer;
forming also over the epitaxial base layer a pair of outward facing spacers, the pair of outward facing spacers being laminated to a pair of sides of the pair of inward facing spacers opposite the aperture; and
forming into the aperture and contacting the epitaxial base layer an emitter layer.

8. The method of claim 7 wherein the epitaxial base bipolar transistor is an N-P-N epitaxial base bipolar transistor.

9. The method of claim 7 wherein the epitaxial base bipolar transistor in a P-N-P epitaxial base bipolar transistor.

10. The method of claim 7 wherein the epitaxial base layer is formed from an epitaxial base material selected from the group consisting of silicon epitaxial materials, germanium epitaxial materials and silicon-germanium alloy epitaxial materials.

11. The method of claim 7 wherein;
the pair of inward facing spacers is formed from a material selected from the group consisting of dielectric materials and semiconductor materials; and
the pair of outward facing spacers is formed from a dielectric material.

12. The method of claim 7 further comprising forming a pair of extrinsic base regions within the semiconductor substrate, the pair of extrinsic base regions being separated by and aligned with the pair of outward facing spacers.
